(19) United States
(12) Patent Application Publication
(10) Pub. No.: US 2010/0128443 A1
(43) Pub. Date: May 27, 2010

(54) HEAT DISSIPATING MODULE

(75) Inventor: Tsun-Sung Chen, Taoyuan Hsien (TW)

Correspondence Address: KIRTON AND MCCONKIE, 60 EAST SOUTH TEMPLE,, SUITE 1800, SALT LAKE CITY, UT, 84111, US

(73) Assignee: DELTA ELECTRONICS, INC., Taoyuan Hsien (TW)

(21) Appl. No.: 12/501,561

(22) Filed: Jul. 13, 2009

(30) Foreign Application Priority Data
Nov. 26, 2008 (TW) 097145796

(51) Int. Cl. H05K 7/20; F28F 7/00

(52) U.S. Cl. 361/710; 165/185

(57) ABSTRACT

A heat dissipating module is mounted on a circuit board. The circuit board includes at least an insertion hole. The heat dissipating module includes a heat sink and at least a fixing element. The heat sink has at least a guiding track, wherein at least an electronic component is attached on the heat sink or the circuit board. The fixing element includes a first fixing part and a second fixing part. The first fixing part is embedded in the guiding track. The second fixing part is partially penetrated through the insertion hole and sustained against a lower surface of the circuit board, thereby facilitating fixing the heat sink on the circuit board.

### FIELD OF THE INVENTION

The present invention relates to a heat dissipating module, and more particularly to a heat dissipating module having a mechanism for facilitating fixing a heat sink on a circuit board.

### BACKGROUND OF THE INVENTION

With the rapid progress of semiconductor industries, the integrated circuits (ICs) used in electronic apparatuses are developed toward minimization, high operating speed and increasing integration level. Due to the reduced size and the increased performance, power semiconductor devices such as power transistors have achieved a great deal of advance. The power transistors are used in many electronic apparatuses such as control equipment, measuring equipment, electrical apparatuses and computer peripheral devices because they are very suitable to process high-power signals. During operation of the electronic apparatus, the power transistors may generate energy in the form of heat, which is readily accumulated and difficult to dissipate away. If no proper heat-dissipating mechanism is provided to transfer enough heat to the ambient air, the elevated operating temperature may result in damage of the electronic components, a breakdown of the whole electronic apparatus or reduced operation efficiency. Therefore, it is important to dissipate the heat generated from the power transistors in order to stabilize the operation and extend the operational life of the electronic apparatus.

For dissipating the heat generated from the electronic components, a variety of heat sinks are attached onto a surface of the circuit board of the electronic device. By means of the heat sink, the heat generated from the electronic components on the circuit board is transferred to the ambient air. Since the heat sink is developed toward increased heat transfer area and reduced thermal resistance, it is important to provide a process of assembling the heat sink in a simplified manner.

Generally, the power transistors are fastened onto a surface of a heat sink in order to increase heat-dissipating efficiency. FIG. 1A is a schematic layout configuration of a circuit board. As shown in FIG. 1A, the circuit board 10 includes an upper surface 101 and a lower surface 102, which are opposed to each other. Several electronic components 11 are mounted on the upper surface 101 of the circuit board 10. The electronic components 11 include for example at least a transistor, at least a resistor, at least a capacitor, at least a diode, at least a magnetic element and the like. The power converting circuit cooperatively defined by these electronic components 11 and the trace pattern of the circuit board 10 is responsible for power conversion. In addition, at least one heat sink 12 is fixed on the upper surface 101 of the circuit board 10 for dissipating heat generated from the electronic components 11. For example, as shown in FIG. 1A, the heat sink 12 is substantially a flat metallic plate. The heat sink 12 has a first surface 121, a second surface 122 and several perforations 123.

FIG. 1B is a schematic perspective view illustrating the backside of the heat sink shown in FIG. 1A. Please refer to FIGS. 1A and 1B. A power transistor 111 is fastened onto the second surface 122 of the heat sink 12. Furthermore, several fixing elements 13 are disposed on the second surface 122 of the heat sink 12. Each fixing element 13 comprises a first part 131 and a second part 132. The first part 131 is substantially perpendicular to the second part 132. Several openings 133 are formed in the first part 131 and aligned with corresponding perforations 123 of the heat sink 12. By penetrating a screw 14 through the openings 133 and corresponding perforations 123, the fixing elements 13 are fastened on the heat sink 12. After the fixing elements 13 are fastened on the heat sink 12, the heat sink 12 is turned over. Then, the tips of the second parts 132 of the fixing elements 13 are penetrated through corresponding insertion holes (not shown) of the circuit board 10. The tips of the fixing elements 13 are then twisted by an angle (as shown in FIG. 1C), so that the tips of the fixing elements 13 are sustained against the sidewalls of the insertion holes. The backside of the resulting structure is shown in FIG. 1C. Meanwhile, the heat sink 12 is fixed on the circuit board 10 through the fixing elements 13. As shown in FIGS. 1B and 1C, after the pins 111a of the power transistor 111 are penetrated through the corresponding insertion holes (not shown) of the circuit board 10, solder paste 15 is applied to the insertion holes in order to bond the power transistor 111 on the circuit board 10.

The process of fixing the heat sink on the circuit board includes the steps of: fixing the fixing elements 13 in corresponding perforations 123 of the heat sink 12, penetrating the tips of the fixing elements 13 through corresponding insertion holes of the circuit board 10, and twisting the tips of the fixing elements 13 by an angle. This process is labor-intensive, time-consuming and troublesome. Moreover, since the fixing elements 13 are fixed in corresponding perforations 123 of the heat sink 12, the flexibility of arranging the fixing elements 13 is restricted because the fixing elements 13 are only located on specified positions.

There is a need of providing an improved a heat dissipating module to obviate the drawbacks encountered from the prior art.

### SUMMARY OF THE INVENTION

It is an object of the present invention to provide a heat dissipating module having a mechanism for facilitating fixing a heat sink on a circuit board.

Another object of the present invention provides a heat dissipating module that is assembled in a simplified, labor-saving and time-saving manner.

A further object of the present invention provides a heat dissipating module comprising a heat sink and at least a fixing element, in which the location of the fixing element is varied as required.

In accordance with an aspect of the present invention, there is provided a heat dissipating module mounted on a circuit board. The circuit board includes at least an insertion hole. The heat dissipating module includes a heat sink and at least a fixing element. The heat sink has at least a guiding track, wherein at least an electronic component is attached on the heat sink or the circuit board. The fixing element includes a first fixing part and a second fixing part. The first fixing part is embedded in the guiding track. The second fixing part is partially penetrated through the insertion hole and sustained against a lower surface of the circuit board, thereby facilitating fixing the heat sink on the circuit board.

In accordance with another aspect of the present invention, there is provided an electronic device. The electronic device includes a housing, a circuit board, a heat sink, at least an electronic device and at least a fixing element. The housing has a receptacle therein. The circuit board is disposed within the housing and includes at least an insertion hole. The heat sink has at least a guiding track. The electronic device is attached on the heat sink or the circuit board. The fixing element includes a first fixing part and a second fixing part. The first fixing part is embedded in the guiding track. The second fixing part is partially penetrated through the insertion hole and sustained against a lower surface of the circuit board, thereby facilitating fixing the heat sink on the circuit board.

The above contents of the present invention will become more readily apparent to those ordinarily skilled in the art after reviewing the following detailed description and accompanying drawings, in which:

### BRIEF DESCRIPTION OF THE DRAWINGS

FIG. 1A is a schematic layout configuration of a circuit board;

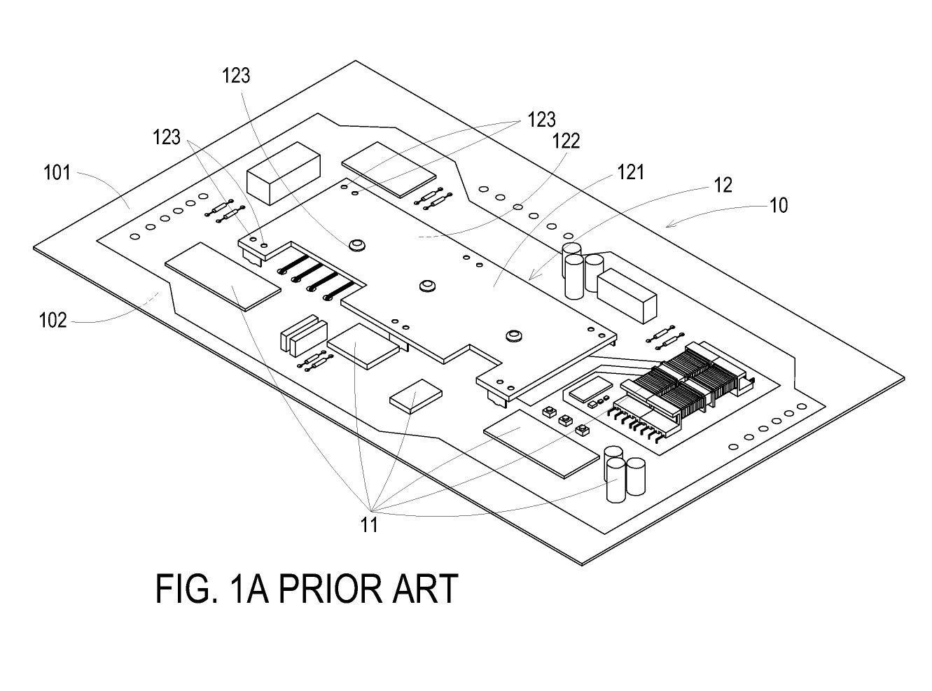

FIG. 1B is a schematic perspective view illustrating the backside of the heat sink shown in FIG. 1A;

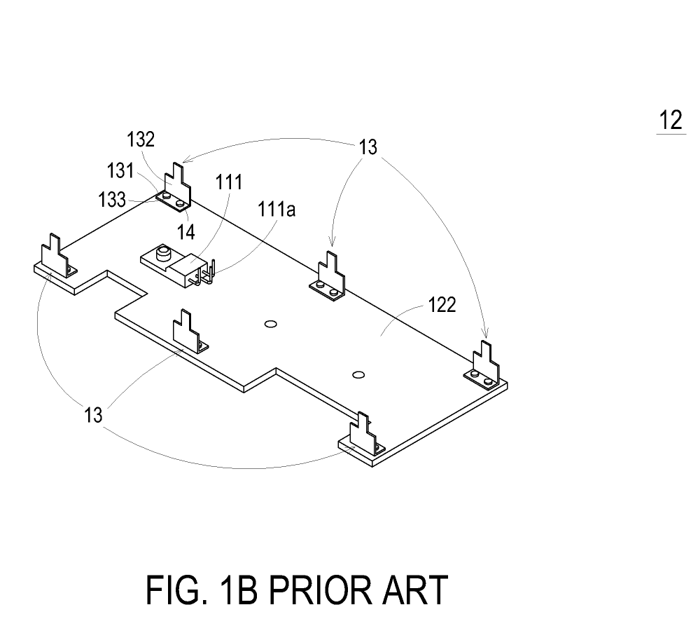

FIG. 1C is a schematic perspective view illustrating the backside of the circuit board shown in FIG. 1A;

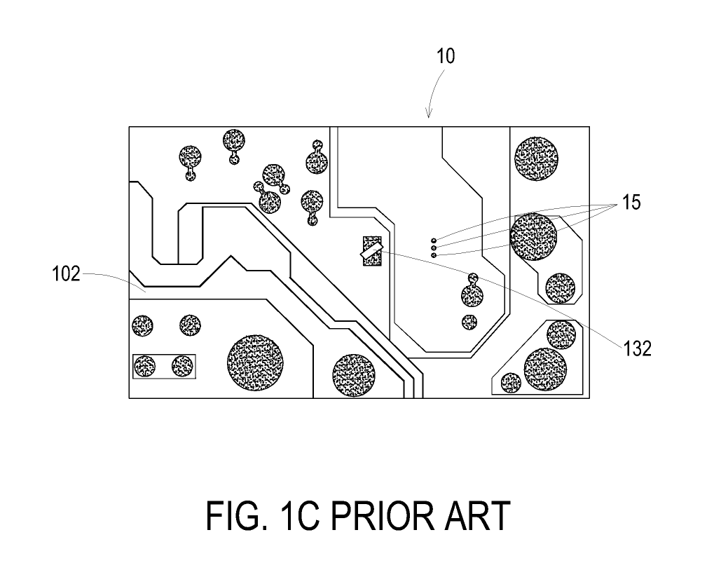

FIG. 2 is a schematic cross-sectional view illustrating an electronic device according to the present invention; and

FIG. 3A is a schematic exploded view illustrating a heat dissipating module according to a preferred embodiment of the present invention; and

FIG. 3B is a schematic assembled view of the heat dissipating module shown in FIG. 3A.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

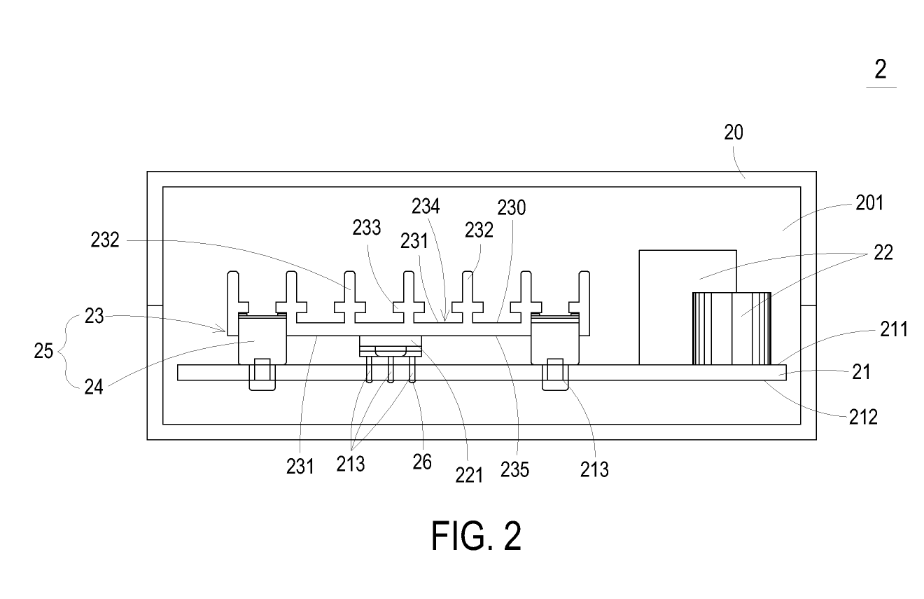

FIG. 2 is a schematic cross-sectional view illustrating an electronic device according to the present invention. The electronic device 2 comprises a housing 20, a circuit board 21, one or more electronic components 22 and a heat dissipating module 25. The electronic components 22 and the heat dissipating module 25 are mounted on the circuit board 21. A receptacle 201 is defined within the housing 20 for accommodating the circuit board 21 as well as the electronic component 22 and the heat dissipating module 25. The heat dissipating module 25 comprises a heat sink 23 and a fixing mechanism. The fixing mechanism comprises several fixing elements 24. The fixing element 24 is used for facilitating fixing the heat sink 23 on the circuit board 21. The heat sink 23 is used for dissipating heat generated from the electronic components 22 that are attached on the circuit board 21 or the heat sink 23. For example, a power transistor 221 is attached on the heat sink 23.

An example of the electronic device 2 includes but is not limited to a power supply apparatus. The circuit board 21 is for example a printed circuit board. As shown in FIG. 2, the circuit board 21 includes an upper surface 211, a lower surface 212 and several insertion holes. The upper surface 211 and the lower surface 212 are opposed to each other. Several electronic components 22 are mounted on the upper surface 211 of the circuit board 21. The electronic components 22 include for example at least a transistor, at least a resistor, at least a capacitor, at least a diode, at least a magnetic element and the like. The power converting circuit cooperatively defined by these electronic components 22 and the trace pattern of the circuit board 21 is responsible for power conversion. In addition, the heat sink 23 is fixed on the upper surface 211 of the circuit board 21 for dissipating heat generated from the electronic components 22. In this embodiment, the heat sink 23 is an aluminum extrusion element. It is preferred that the heat sink 23 is integrally formed.

Please refer to FIG. 2 again. The heat sink 23 has a first surface 230 and a second surface 235. The first surface 230 and the second surface 235 are opposed to each other. The heat sink 23 principally comprises a first part 231, a second part 232 and a third part 233, which are disposed on the first surface 230 of the heat sink 23. The first part 231 of the heat sink 23 is substantially parallel with the circuit board 21. The second part 232 of the heat sink 23 is arranged on the first part 231 and vertically extended from the upper surface 211 of the circuit board 21. In particular, the second parts 232 are fins for increasing the overall heat transfer area of the heat sink 23. The number of the second parts 232 may be varied according to the practical requirements. The third part 233 is arranged on the second part 232. The third part 233 is substantially perpendicular to the second part 232 but parallel to the first part 231. In accordance with a key feature of the present invention, the first part 231, the second part 232 and the third part 233 collectively define a guiding track 234.

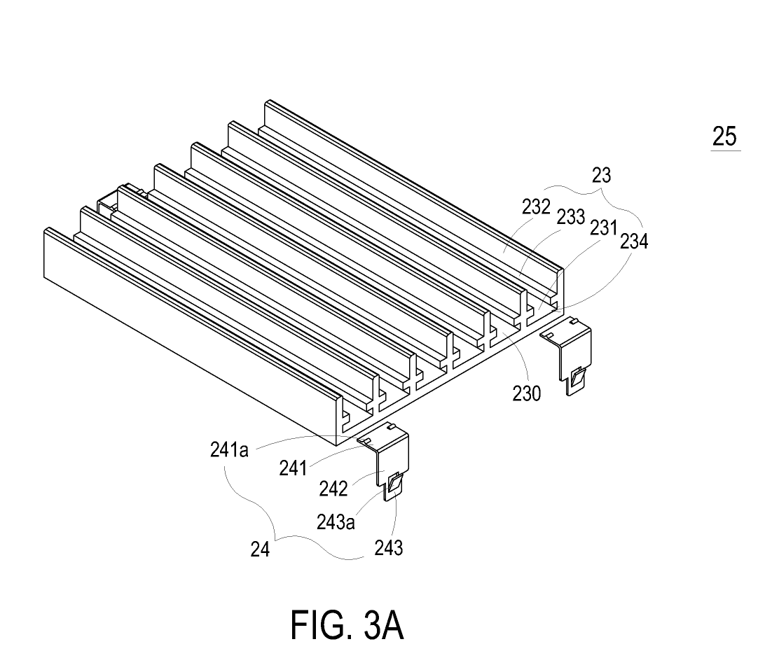

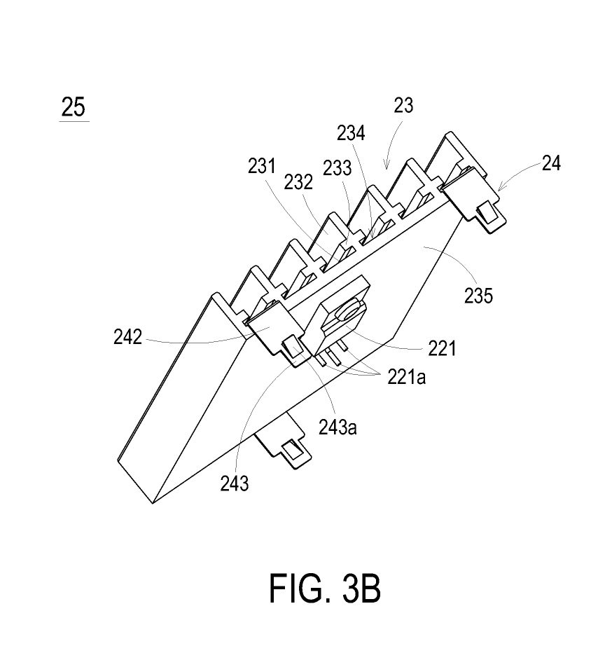

FIG. 3A is a schematic exploded view illustrating a heat dissipating module according to a preferred embodiment of the present invention. As shown in FIGS. 2 and 3A, the fixing mechanism comprises several fixing elements 24. Each fixing element 24 has a first fixing part 241 and a second fixing part 242. The first fixing part 241 is embedded in the guiding track 234, and the second fixing part 242 is partially penetrated through the insertion hole 213 and sustained against a lower surface 212 of the circuit board 21. In addition, an insertion part 243 is formed at the terminal of the second fixing part 242. The diameter of the insertion part 243 is smaller than that of a corresponding insertion hole 213 of the circuit board 21, so that the insertion part 243 can be penetrated through the insertion hole 213. It is preferred that the first fixing part 241, the second fixing part 242 and the insertion part 243 are made of metallic material and integrally formed.

In addition, a first engaging part 241a and a second engaging part 243a are formed on the first fixing part 241 and the insertion part 243, respectively. In some embodiments, the first engaging part 241a and the second engaging part 243a are hooks that are adjacent corresponding slots and have respective slant surfaces, and thus the first engaging part 241a and the second engaging part 243a are resilient. In a case that the first engaging part 241a is inserted into the guiding track 234 of the heat sink 23, the first engaging part 241a is firstly compressed by the third part 233 of the heat sink 23, and the compressed first engaging part 241a is restored due to the elastic force thereof. Consequently, the first engaging part 241a is sustained against the third part 233 of the heat sink 23 and the fixing element 24 is fixed onto the heat sink 23.

FIG. 3B is a schematic assembled view of the heat dissipating module shown in FIG. 3A. As shown in FIG. 3B, the heat sink 23 has a plurality of guiding tracks 234 of the same dimension. The fixing elements 24 may be embedded into respective guiding tracks 234 at any desired positions according to the practical requirements. In other words, the flexibility of using the fixing elements 24 is enhanced. Moreover, since the fixing elements 24 are identical and the heat sink 23 is easily produced, the heat dissipating module 25 of the present invention is more advantageous over the conventional heat dissipating module.

Please refer to FIGS. 2 and 3B again. The power transistor 221 is fastened on the second surface 235 of the heat sink 23 such that the heat sink may facilitate dissipating the heat generated from the power transistor 221. After the pins 221a of the power transistor 221 are penetrated through the corresponding insertion holes 213 of the circuit board 21, solder paste 26 is applied to the insertion holes 213 in order to bond the power transistor 221 on the lower surface 212 of the circuit board 21.

Please refer to FIGS. 2 and 3B again. For fixing the heat dissipating module 25 on the circuit board 21, the heat dissipating module 25 is firstly placed on the upper surface 211 of the circuit board 211 and then the insertion parts 243 are aligned with corresponding insertion holes 213 of the circuit board 21. Next, the insertion parts 243 are inserted into corresponding insertion holes 213 of the circuit board 21. During the insertion parts 243 are inserted into corresponding insertion holes 213, the second engaging parts 243a are compressed by the sidewalls of the insertion holes 213. After the second engaging parts 243a are completely penetrated through the insertion holes 213, the second engaging parts 243a are restored due to the elastic forces thereof, so that the second engaging parts 243a are sustained against the lower surface 212 of the circuit board 21. Consequently, the heat sink 23 is securely fixed onto the circuit board 21. Since the procedure of turning over the circuit board and twisting the tips of the fixing elements are omitted, the process of mounting the heat dissipating module on the circuit board according to the present invention is largely simplified and more user-friendly.

From the above description, the heat dissipating module of the present invention includes a heat sink and a mechanism for facilitating fixing the heat sink on a circuit board. For enhancing the heat dissipating efficiency, the number of fins on the heat sink may be increased. Since the fixing elements may be embedded into respective guiding tracks at any desired positions, the flexibility of using the fixing elements is enhanced. Moreover, since the procedure of turning over the circuit board and twisting the tips of the fixing elements are omitted, the process of mounting the heat dissipating module on the circuit board according to the present invention is largely simplified and more user-friendly

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A heat dissipating module mounted on a circuit board, said circuit board including at least an insertion hole, said heat dissipating module comprising:
a heat sink having at least a guiding track, wherein at least an electronic component is attached on said heat sink or said circuit board; and
at least a fixing element comprising a first fixing part and a second fixing part, wherein said first fixing part is embedded in said guiding track, and said second fixing part is partially penetrated through said insertion hole and sustained against a lower surface of said circuit board, thereby facilitating fixing said heat sink on said circuit board.

2. The heat dissipating module according to claim 1 wherein said heat sink is an aluminum extrusion element.

3. The heat dissipating module according to claim 1 wherein said heat sink comprises a first part and a second part, which are substantially perpendicular to each other.

4. The heat dissipating module according to claim 3 wherein said heat sink comprises a third part, which is arranged on said second part and substantially perpendicular to said second part, and said first part, said second part and said third part collectively define a guiding track.

5. The heat dissipating module according to claim 4 wherein said first fixing part of said fixing element further includes a first engaging part to be sustained against said third part of said heat sink so as to embed said fixing element into said guiding track.

6. The heat dissipating module according to claim 3 wherein said electronic component includes a power transistor, which is attached on said first part of said heat sink.

7. The heat dissipating module according to claim 1 wherein an insertion part is formed at a terminal of said second fixing part to be inserted into said insertion hole of said circuit board.

8. The heat dissipating module according to claim 7 wherein said insertion part of said fixing element further includes a second engaging part to be sustained against said lower surface of said circuit board, thereby facilitating fixing said heat sink on said circuit board.

9. The heat dissipating module according to claim 8 wherein said first engaging part and said second engaging part are hooks having respective slant surfaces.

10. An electronic device comprising:
a housing having a receptacle therein;
a circuit board disposed within said housing and including at least an insertion hole;
a heat sink having at least a guiding track;
at least an electronic device attached on said heat sink or said circuit board; and
at least a fixing element comprising a first fixing part and a second fixing part, wherein said first fixing part is embedded in said guiding track, and said second fixing part is partially penetrated through said insertion hole and sustained against a lower surface of said circuit board, thereby facilitating fixing said heat sink on said circuit board.

11. The electronic device according to claim 10 wherein said heat sink is an aluminum extrusion element.

12. The electronic device according to claim 10 wherein said heat sink comprises a first part and a second part, which are substantially perpendicular to each other.

13. The electronic device according to claim 12 wherein said heat sink comprises a third part, which is arranged on said second part and substantially perpendicular to said second part, and said first part, said second part and said third part collectively define a guiding track.

14. The electronic device according to claim 13 wherein said first fixing part of said fixing element further includes a first engaging part to be sustained against said third part of said heat sink so as to embed said fixing element into said guiding track.

15. The electronic device according to claim 12 wherein said electronic component includes a power transistor, which is attached on said first part of said heat sink.

16. The electronic device according to claim 10 wherein an insertion part is formed at a terminal of said second fixing part to be inserted into said insertion hole of said circuit board.

17. The electronic device according to claim 16 wherein said insertion part of said fixing element further includes a second engaging part to be sustained against said lower surface of said circuit board, thereby facilitating fixing said heat sink on said circuit board.

18. The electronic device according to claim 17 wherein said first engaging part and said second engaging part are hooks having respective slant surfaces.
